(19) United States
(12) Patent Application Publication
(10) Pub. No.: US 2020/0303555 A1
(43) Pub. Date: Sep. 24, 2020

(54) OXIDE SEMICONDUCTOR THIN-FILMS WITH CONTENT GRADIENT

(71) Applicant: The Regents of the University of California, Oakland, CA (US)

(72) Inventors: Yang Yang, Los Angeles, CA (US); Le Cal, Los Angeles, CA (US); Guangwei Xu, Los Angeles, CA (US); Zhengxu Wang, Los Angeles, CA (US); Yepin Zhao, Los Angeles, CA (US); Jun Yang, West Covina, CA (US)

(73) Assignee: The Regents of the University of California, Oakland, CA (US)

(21) Appl. No.: 16/823,121

(22) Filed: Mar. 18, 2020

Related U.S. Application Data
(60) Provisional application No. 62/820,617, filed on Mar. 19, 2019.

(51) Int. Cl. H01L 29/786; H01L 21/02; H01L 21/477; H01L 29/66; H01L 29/24; H01L 29/45; H01L 29/49

(52) U.S. Cl. CPC H01L 29/7869; H01L 21/02565; H01L 21/02628; H01L 21/477; H01L 29/78696; H01L 29/24; H01L 29/45; H01L 29/4908; H01L 29/78648; H01L 29/66969

(57) ABSTRACT

An electronic device includes a first electrode, and a second electrode spaced apart from the first electrode. The electronic device further includes a conduction channel in electrical connection with the first and second electrodes so as to be able to conduct a charge carrier current between the first and second electrodes along a condition path during an operating condition. The conduction channel has a gradient semiconductor oxide composition transverse to the conduction path such that the gradient semiconductor oxide composition varies from indium rich to gallium rich.

### CROSS REFERENCE TO RELATED APPLICATIONS

The present patent application claims priority benefit to U.S. provisional application No. 62/820,617, filed on Mar. 19, 2019, the entire content of which is incorporated herein by reference.

### BACKGROUND

The field of the currently claimed embodiments of this invention relates to electronic devices and methods of producing the electronic devices, and more particularly to electronic devices and methods of producing the electronic devices to have an oxide thin film with content gradient.

### SUMMARY

An aspect of the present invention is to provide an electronic device. The electronic device includes a first electrode; and a second electrode spaced apart from the first electrode. The device further includes a conduction channel in electrical connection with the first and second electrodes so as to be able to conduct a charge carrier current between the first and second electrodes along a condition path during an operating condition. The conduction channel has a gradient semiconductor oxide composition transverse to the conduction path such that the gradient semiconductor oxide composition varies from indium rich to gallium rich.

Another aspect of the present invention is to provide a method of producing a conduction channel for an electronic device. The method includes forming a first indium-rich metal-oxide gel film at least one of on or above a substrate; forming a second indium rich metal-oxide gel film at least one of on or above the first indium-rich metal-oxide gel film, the second indium rich metal-oxide gel film being less indium rich than the first indium-rich metal-oxide gel film; forming a gallium-rich metal-oxide gel film at least one of on or above the second indium-rich metal-oxide gel film; and annealing the conduction channel to remove solvent molecules and volatile impurity elements and to form a cross-linked metal-oxygen framework.

Yet another aspect of the present invention is to provide an electronic device produced according to the above method.

### BRIEF DESCRIPTION OF THE DRAWINGS

The present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

FIG. 1A shows a flow diagram of method of a multiple-layer stacking, according to an embodiment of the present invention;

FIG. 1B is a schematic representation of an electronic device structure, according to the current invention;

FIGS. 2A-2D are plots of current drain-source (I_{DS}) versus voltage gate-source (V_{GS}), according to embodiments of the present invention;

FIG. 3A-3D are plots of current drain-source (I_{DS}) versus a voltage gate-source (V_{GS}) representing transfer characteristics before (solid) and after (dashed) depositing 80 nm SiO2 by PECVD as passivation layer for devices with different materials as channel semiconductors, according to embodiments of the present invention;

FIG. 4A-4D show positive bias stress (PBS) test results of a GZO/221/912 device with 80 nm PECVD-SiO₂ passivation layer, according to an embodiment of the present invention;

FIGS. 5A-5B show transfer curves before (solid lines) and after (dashed lines) PBS at 20 V (2 MV/cm) for 10000 s for various devices, according to an embodiment of the present invention; and

FIGS. 6A-6F show schematic representations of additional examples of electronic device structures, according to some embodiments of the current invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

Some embodiments of the current invention are directed to methods to prepare metal-oxide semiconductor thin-films with cation concentration gradient by sol-gel processes and their application as channel materials to realize thin film transistors (TFTs) with high field-effect mobility and good stability as compared to thin-films with uniform cation distribution. According to an embodiment, heterogeneous gel-films are first formed by alternatively spin-coating precursor solutions with different compositions. Ion diffusion occurs during an ensuing thermal annealing process that leads to the desired cation ion concentration gradient. The following describes the example of metal oxide semiconductors consisting of post-transition metal ions such as indium, gallium, zinc and tin, prepared by a method according to an embodiment of the current invention. Indium-rich films (such as In₂O₃, 9:1:2 InGaZnO, InZnO, etc.) are used as the bottom layer to provide high carrier density and fast electronic conduction pathways, while gallium-rich films (such as Ga₂O₃, GaZnO, etc.) are used on the top to suppress the off-state current and improve the stability under harsh environments. Detailed description of the data can be found below.

### A) Details of an Embodiment

1. Precursor solution preparation: Metal salts, such as In(NO₃)₃, Ga(NO₃)₃, Zn(CH₃COO)₂, are dissolved in appropriate solvents such as 2-methoxyethanol or water, with a total metal ion concentration of 0.1 M. Acetylacetone is added as a solution stabilizer. The solution is stirred and ages for 3-6 hours before use. The general concepts of the current invention are not limited to only these particular precursor solutions, nor to the particular aging time.

2. Metal-oxide thin-film formation: The precursor solution prepared in step 1 is spin-coated on a Si wafer, glass or plastic substrates with a spinning speed of about 2000-4000 rpm and time of 10-30 seconds. The substrates are cleaned and treated by UV ozone for at least 20 minutes before spin coating the precursor solution. After spin coating, soft-baking at 100-200° C. for 1-5 min renders a gel film. Multiple runs of spin coating and soft-baking are carried out to achieve desired film thickness or multiple film stacking. Finally, the gel film is annealed at elevated temperatures (200-400° C.) for 1-3 hours to remove solvent molecules and volatile impurity elements, and to form cross-linked metal-oxygen framework. These steps and parameters are examples and do not limit the general concepts of this invention.

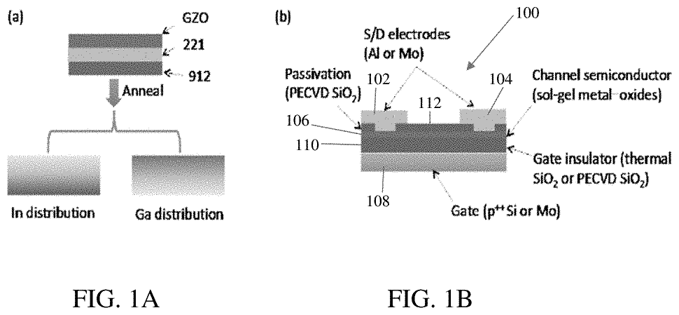

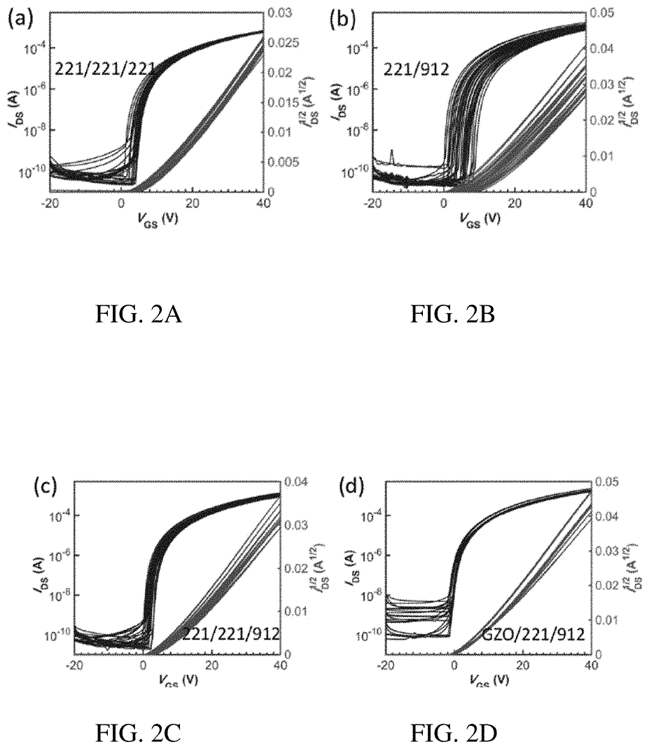

3. Metal-oxide compositional engineering: An embodiment of this invention is directed to use a multiple-layer stacking strategy to realize desired composition engineering. One or more layers of In-rich gel films are first formed on the substrate by successive spin-coating and soft-baking as described in step 2. Then, one or more less-In-rich gel-films are formed by the same method. The general concepts of the current invention are not limited to the particular number of In-rich gel films, nor to the specific difference in composition between layers in the stack. Both the number of layers and the differences in composition between layers can be selected according to the particular application. Subsequently, gallium-rich films are coated and, if needed, more-gallium-rich films can be used to finalize the film formation. The general concepts of the current invention are not limited to the particular number of gallium-rich thin films used, nor to the particular difference in composition between the gallium-rich thin films. Both can be chosen according to the particular application. The multiple-layered films are finally annealed using the method described in step 2. This process eventually produces a metal-oxide thin-film with an indium-content (gallium-content) gradient, as shown in FIG. 1A. As a specific example, we successfully demonstrated a thin-film by successively spin-coating precursor solutions with In, Ga and Zn molar ratios of 9:1:2, 2:2:1, and 0:1:1, respectively (hereafter denoted as GZO/221/912 film). The resulting film has gradually decreasing (increasing) indium (gallium) content from bottom to top. Oxide semiconductor thin films with such content gradient can be advantageous for achieving high field-effect mobility and good stability simultaneously. Indium-rich part at the bottom owns a relatively narrower band gap and provides high-speed electronic conduction pathway while gallium-rich part on the top has a much wider band gap and act as carrier suppressor and a barrier layer that effectively suppresses the influence of surface absorbents such as moisture and oxygen.

FIG. 1A shows a flow diagram of method of a multiple-layer stacking, according to an embodiment of the present invention. As shown in FIG. 1A, before high-temperature annealing, the GZO/221/912 film is composed of a stacking of gel-films with respective cation ratios. After annealing at −400° C. for 3 hours, the gel transforms into a solid and dense metal oxide film with a gradient in In-/Ga-content. As shown in FIG. 1A, the lower part of the film is In-rich that provides a high-speed electronic conduction pathway and high carrier density, while the upper part is Ga-rich and acts as a native passivation layer that protects the electronic conduction part from disturbance from the environment.

Therefore, the method of producing a conduction channel for an electronic device includes 1) forming a first indium-rich metal-oxide gel film at least one of on or above a substrate; 2) forming a second indium rich metal-oxide gel film at least one of on or above the first indium-rich metal-oxide gel film, the second indium rich metal-oxide gel film being less indium rich than the first indium-rich metal-oxide gel film; 3) forming a gallium-rich metal-oxide gel film at least one of on or above the second indium-rich metal-oxide gel film; and 4) annealing the conduction channel to remove solvent molecules and volatile impurity elements and to form a cross-linked metal-oxygen framework.

In an embodiment, the method further includes, before the annealing, forming a third indium rich metal-oxide gel film at least one of on or above the first indium-rich metal-oxide gel film and prior to forming the second indium rich metal-oxide gel film, the third indium rich metal-oxide gel film being less indium rich than the first indium-rich metal-oxide gel film and more indium rich than the second indium-rich metal-oxide gel film.

In an embodiment, the method further includes, before the annealing, forming a second gallium-rich metal-oxide gel film at least one of on or above the first gallium-rich metal-oxide gel film, the second gallium-rich metal-oxide gel film being more gallium rich than the first gallium-rich metal-oxide gel film.

In an embodiment, forming the first indium-rich metal-oxide gel film includes spin coating a first precursor solution followed by a first soft baking. In an embodiment, forming the second indium-rich metal-oxide gel film includes spin coating a second precursor solution followed by a second soft baking. In an embodiment, forming the gallium-rich metal-oxide gel film includes spin coating a third precursor solution followed by a third soft baking.

FIG. 1B is a schematic representation of an electronic device structure, according to the current invention. For example, the electronic device can be made using the above method. As shown in FIG. 1B, typical electronic devices use bottom-gate, top-contact structure, with a passivation layer (e.g., PECVD SiO₂) to further improve the device stability. However, the general concepts of the current invention are not limited to only this example. As shown in FIG. 1B, the electronic device 100 includes a first electrode 102 and a second electrode 104 spaced apart from the first electrode 102. In an embodiment, the first electrode 102 is a source (S) electrode and the second electrode 104 is a drain (D) electrode. In another embodiment, the first electrode 102 is a drain (D) electrode and the second electrode 104 is a source (S) electrode. The first electrode 102 and the second electrode 104 can be made of an electrical conductor such as a metal. For example, the first electrode 102 and the second electrode 104 can be made of aluminum (Al) or molybdenum (Mo), or both.

The device 100 also includes a conduction channel 106. The conduction channel 106 is in electrical connection with the first electrode 102 and second electrode 104 so as to be able to conduct a charge carrier current between the first electrode 102 and the second electrode 104 along a conduction path during an operating condition. The conduction channel 106 includes a gradient semiconductor oxide composition transverse to the conduction path such that the gradient semiconductor oxide composition varies from indium rich to gallium rich, as shown in FIG. 1A. In an embodiment, the conduction channel 106 includes sol-gel meta oxides. In an embodiment, the conduction channel 106 includes GZO/221/912 film. As will be described in the following paragraphs, although GZO/221/912 film is used as an example, any precursor combination that can produce ion concentration gradient and/or bandgap variation along the thickness direction can be used, such as Ga₂O₃/In₂O₃, Ga₂O₃/ZnO, Ga₂O₃/InZnOₓ, GaZnOₓ/In₂O₃, GaZnOₓ/InZnOₓ, ZnO/SnO₂, GaZnO/ZnO, GaZnO/SnO₂, etc.

In an embodiment, the device 100 also includes passivation layer 112 so as to further improve the stability of the device 100. In an embodiment, the passivation layer 112 includes PECVD SiO₂. In an embodiment, as shown in FIG. 1B, the passivation layer (e.g., PECVD SiO₂) is disposed on the conduction channel 106 and between the first electrode 102 and the second electrode 104.

In an embodiment, the electronic device 100 shown in FIG. 1B, further includes a third electrode 108 separated from the first electrode 102, the second electrode 104 and the conduction channel 106 by at least one of a vacuum or an electrical insulator 110. In an embodiment, the third electrode 108 is a gate (G) electrode. In an embodiment, the third electrode (e.g., gate electrode) 108 can include silicon (Si) or molybdenum (Mo), or both. In an embodiment, the electrical insulator 110 can include thermal silicon oxide (SiO₂) or PECVD silicon oxide (SiO₂). In an embodiment, the electrical insulator 110 can also include ALD-deposited Al₂O₃.

4. TFT fabrication: In an embodiment, the metal-oxide thin-film transistor device 100 adopts a bottom-gate, staggered configuration. Heavily doped silicon or pre-formed metal patterns are used as global or local gate, while thermal SiO₂, ALD-deposited Al₂O₃ or PECVD SiO₂ are used as gate insulator. After forming the desired metal-oxide thin-films as channel semiconductors, S/D electrodes are deposited and patterned either through a shadow mask or by lithography. Finally, the devices are encapsulated with PECVD SiO₂ to ensure a good stability under long-term operation.

### B) Possible Commercial Applications and Competitive Benefits

Multi-cation metal-oxides with different compositions, i.e. different ratios of various metal ions, exhibit distinct electronic properties. Indium-rich oxides feature high carrier concentration because of the low dissociation energy of In—O bonds and thus high concentration of oxygen-vacancies, the primary contributor of free carriers, and high carrier mobility due to the large overlaps between neighboring spherical 5s-orbitals of indium that provide more electronic conduction pathways. Consequently, indium-rich films result in TFTs with high output-current. However, the tendency of forming oxygen-vacancies leads to poor stability of In-rich films and makes it difficult to achieve TFTs with enhancement operation mode that is desired for low power consumption devices. In contrast, gallium-rich oxides own relatively wider band gap, much lower carrier concentration and better stability due to the strong bonding between gallium and oxygen. Therefore, gallium ions are used as carrier density suppressor and to improve device stability.

High-performance metal-oxide semiconductors were initially obtained by sputtering that is currently widely used in industry. However, sputtering is an expensive technique and the substrate size is limited by the vacuum chamber. In addition, the film composition cannot be tuned at will because of the fixed composition of targets. In comparison, sol-gel process is an attractive alternative to produce metal-oxide semiconductors in a low-cost and scalable fashion. Additionally, sol-gel is advantageous for easy compositional tuning by choosing different precursors, solvents and additives. Nonetheless, device performance, in particular field-effect mobility and device stability, of metal-oxide semiconductors produced by sol-gel method has lagged behind those produced by sputtering.

Our multiple-layer-stacking method according to an embodiment of the current invention produces metal-oxide thin films with unique composition gradient and exhibits significantly improved device performance compared to metal-oxide thin films with uniform cation distribution. In our specific example, the key findings include:

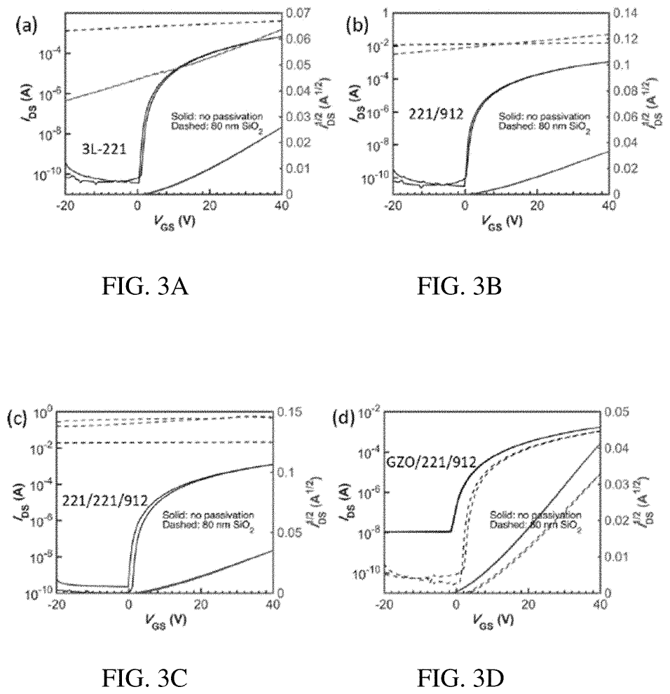

1. The GZO/221/912 films show mobility much higher than pure 221 films and no less than pure 912 films. FIGS. 2A-2D are plots of current drain-source (I_{DS}) versus voltage gate-source (V_{GS}), according to embodiments of the present invention. FIGS. 2A-2D show transfer characteristics of thin-film transistors using different materials as channel semiconductors, according to embodiments of the present invention. FIG. 2A shows transfer characteristics in a 3-layer 221 (In:Ga:Zn ratio) film. FIG. 2B shows transfer characteristics in a 221/912 (top/bottom) bi-layer film. FIG. 2C shows transfer characteristics in a 221/221/912 tri-layer film. FIG. 2D shows transfer characteristics in a GZO/221/912 tri-layer film. Current-voltage curves for at least 10 devices are shown in FIGS. 2A-2D. The left current-voltage curves correspond to I_{DS} vs. V_{GS} and the right current-voltage curves correspond to I_{DS}^{1/2} vs. V_{GS}.

TABLE I reports field-effect mobility of channel semiconductors shown in FIGS. 2A-2D.

TABLE I

| Channel Materials | Mobility (cm²/Vs) |
|---|---|
| 221/221/221 | 4.02 ± 0.61 |
| 221/912 | 7.4 ± 0.59 |
| 221/221/912 | 5.85 ± 0.44 |
| GZO/221/912 | 9.29 ± 0.59 |

The above results in Table I and FIGS. 2A-2D are very impressive results considering the fact that pure gallium doped zinc oxide (GZO) films show nearly insulating behaviors. This indicates that the GZO layer in the heterogeneous film is rendered conductive by ion diffusion among different layers of the films.

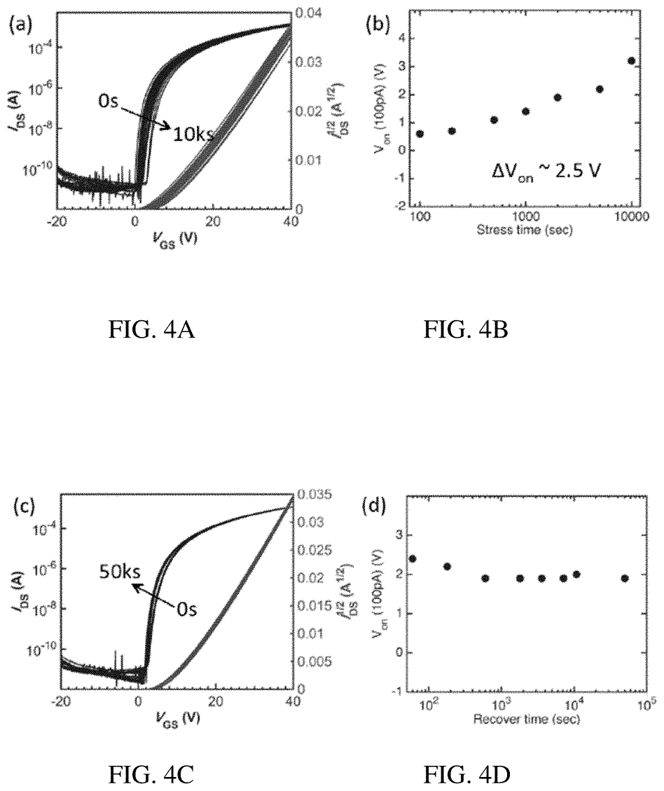

2. More importantly, with the high-gallium top layer, GZO/221/912 films are proven to be robust enough to survive plasma treatment. FIG. 3A-3D are plots of current drain-source (I_{DS}) versus a voltage gate-source (V_{GS}) representing transfer characteristics before (solid) and after (dashed) depositing 80 nm SiO₂ by PECVD as passivation layer for devices with different materials as channel semiconductors, according to embodiments of the present invention. FIG. 3A shows transfer characteristics for a 3-layer 221 (In:Ga:Zn ratio) film. FIG. 3B shows transfer characteristics for a 221/912 (top/bottom) bi-layer film. FIG. 3C shows transfer characteristics for a 221/221/912 tri-layer film. FIG. 3D shows transfer characteristics for a GZO/221/912 tri-layer film.

The pure 221 or 912 films form a surface conductive layer after being treated with mild plasma and thus lose their transistor functionality. In contrast, GZO/221/912 film retain its transistor performance without noticeable shift in turn-on voltage after being treated with plasma, making it possible to deposit a layer of PECVD SiO₂ as passivation layer to further improve the device stability.

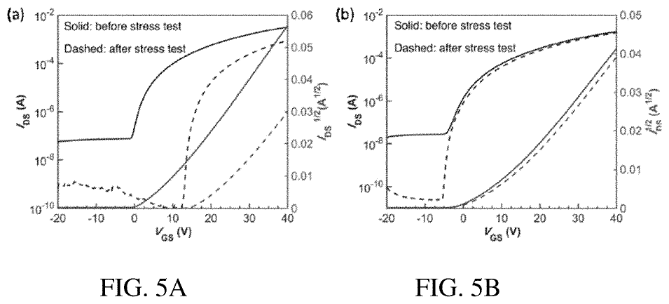

3. The TFTs with GZO/221/912 film as channel semiconductor and passivated with PECVD SiO₂ show significantly improved stability under long time positive gate bias stress (PBS) test, with a Vₒₙ shift of 2.5 V under PBS of 20 V (2 MV/cm) for 10000 seconds (See FIG. 4A-4D). FIG. 4A-4D show positive bias stress (PBS) test results of a GZO/221/912 device with 80 nm PECVD-SiO₂ passivation layer, according to an embodiment of the present invention. FIG. 4A shows the evolution of transfer characteristics during the process of PBS test for 10⁴ seconds at a gate-source bias of 20 V (2 MV/cm). FIG. 4B shows turn-on voltage (Vₒₙ, defined as the V_{GS} when I_{DS} is equal to 100 pA) as a function of PBS time. After 10⁴ seconds, Vₒₙ shifted to the right by approximately 2.5 V. FIG. 4C shows the evolution of transfer characteristics during the process of recovery for 5×10⁴ seconds (shown by the arrow) with the gate-source voltage bias (V_{GS}) kept at 0 V. FIG. 4D shows turn-on voltage as a function of recovery time. The device performance showed negligible change during the recovery process.

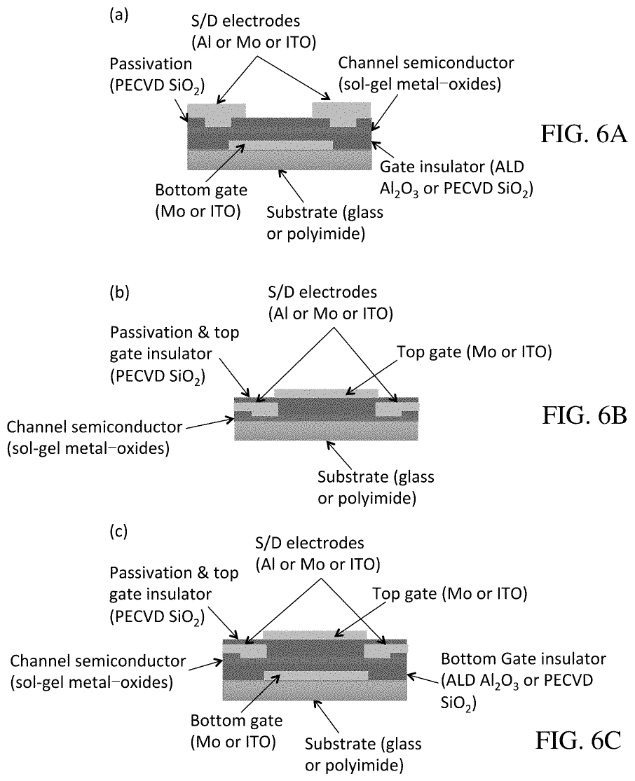

In comparison, devices with 221/912 channel show a Vₒₙ shift of >10 V with the same PBS duration. We observed similar stability enhancement in Ga₂O₃/InZnO bilayer structured thin films (See, FIGS. 5A-5B). With a layer of Ga₂O₃ as protection, ΔVₒₙ is reduced from 13 V to 0.6 V. FIGS. 5A-5B show transfer curves before (solid lines) and after (dashed lines) PBS at 20 V (2 MV/cm) for 10000 s for various devices, according to an embodiment of the present invention. FIG. 5A shows a transfer curve for a device with pure InZnO. FIG. 5B shows a transfer curve for a device with a Ga₂O₃/InZnO bilayer as channel semiconductors. InZnO shows a dramatic Vₒₙ shift (approximately 13 V), while Ga₂O₃/InZnO shows negligible shift (only 0.6 V) after the stress test.

Regardless of the specific example of GZO/221/912 films, our method can provide the following additional benefits:

1. Simplicity and versatility: In an embodiment, the method described herein is very simple to implement and easy to follow. Although GZO/221/912 film is used as an example, any precursor combination that can produce ion concentration gradient and/or bandgap variation along the thickness direction can be used, such as Ga₂O₃/In₂O₃, Ga₂O₃/ZnO, Ga₂O₃/InZnOₓ, GaZnOₓ/In₂O₃, GaZnOₓ/InZnOₓ, ZnO/SnO₂, GaZnO/ZnO, GaZnO/SnO₂, etc. It is also a universal strategy to combine multiple merits in one single system, whereas the metal-oxide semiconductors consisting of In, Ga and Zn are just one example. For example, multiferroic thin-films with similar content gradient may be realized by using materials that exhibit ferroelectric or ferromagnetic properties depending on their chemical compositions.

2. Low-cost and scalability: This method naturally inherits the merits of solution processes, i.e., being low-cost and easy for scalable fabrication. In this specific example, the GZO/221/912 films show device performance that is comparable with that of sputtered IGZO films, yet with much simpler deposition procedures, lower cost and no limit in substrate size.

3. Controllability: This method is especially useful when precise compositional control of sol-gel film is required. In ordinary solution processes, although the ratio of different metal ions in precursor solutions can be easily tuned by precisely controlling the amount of metal salts, harnessing the composition of the final metal-oxide thin-films has been challenging due to the mismatch in ion size, interaction with ligands and adhesion on substrate surface for different metal ions. As a result, the resulting sol-gel film usually has radically different composition than that expected by directly deriving from the precursor solution. In addition, content gradient cannot be controllably achieved by merely tuning the constituent concentration or ligand interaction in precursor solutions. In contrast, the method invented here can produce sol-gel films with desired compositions and composition distribution through the film thickness in a controllable manner.

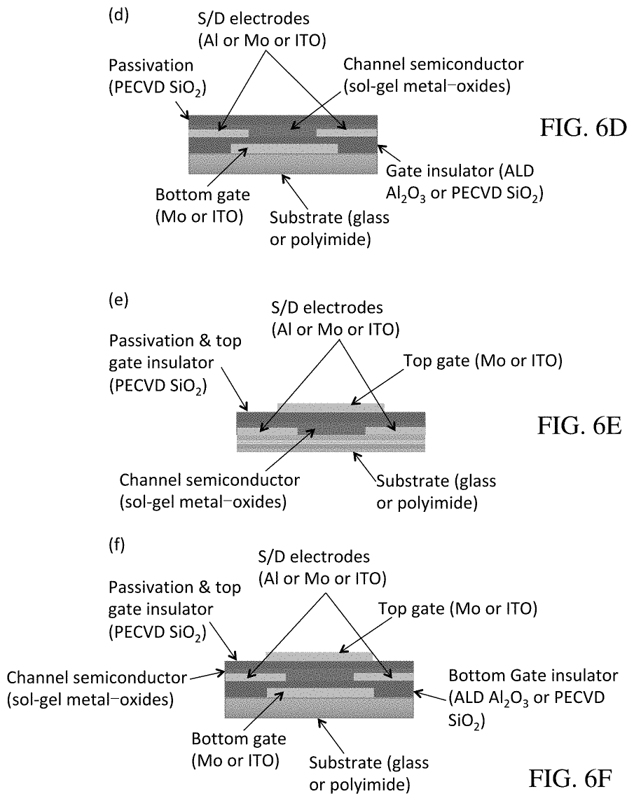

FIGS. 6A-6F show schematic representations of additional examples of electronic device structures, according to some embodiments of the current invention. The devices have a sol-gel metal oxide channel semiconductor according to some embodiments of the current invention. However, the general concepts of the current invention are not limited to only these examples.

FIG. 6A shows a schematic representation of an electronic device having a third electrode, e.g., a bottom gate (e.g., molybdenum (Mo) or indium tin oxide (ITO)) and a top contact. As shown in FIG. 6A, the bottom gate is provided on a substrate (e.g., glass or polyimide). Similar to the embodiment shown in FIG. 1B, the third electrode (bottom gate) is separated from the first electrode (e.g., source), the second electrode (e.g., drain) and the conduction channel (e.g., having sol-gel metal oxides) by at least one of a vacuum or an electrical insulator (gate insulator such as ALD Al₂O₃ or PECVD SiO₂).

FIG. 6B shows a schematic representation of an electronic device having a top gate (e.g., Mo or ITO) and a top contact. In this embodiment, the conduction channel (e.g., having sol-gel meta-oxides) is provided on a substrate (e.g., glass or polyimide). The third electrode (in this case a top gate having for example Mo or ITO) is separated from the first electrode (e.g., source), the second electrode (e.g., drain) and the conduction channel (e.g., having sol-gel metal oxides) by at least one of a vacuum or an electrical insulator (passivation and top gate insulator such as PECVD SiO₂).

FIG. 6C shows a schematic representation of an electronic device having two gates (bottom and top gates) and top contact. The bottom gate (e.g., having Mo or ITO) is provided on a substrate such as a glass or a polyimide substrate. The top gate (e.g., having Mo or ITO) is provided on top of a passivation and top gate insulator (e.g., PECVD SiO₂). Similar to the embodiment shown in FIG. 1B, the electronic device shown in FIG. 6C also includes a conduction channel (e.g., having sol-gel metal oxides) that is provided between the top and bottom gates. The bottom gate is separated from the first electrode (e.g., source), the second electrode (e.g., drain) and the conduction channel (e.g., having sol-gel metal oxides) by at least one of a vacuum or an electrical insulator (bottom gate insulator). The top gate is separated from the first electrode (e.g., source), the second electrode (e.g., drain) and the conduction channel (e.g., having sol-gel metal oxides) by at least one of a vacuum or an electrical insulator (passivation and top gate insulator).

FIG. 6D shows a schematic representation of an electronic device having a bottom gate (e.g., Mo or ITO) and bottom contact. The bottom gate is provided on a substrate (e.g., glass or polyimide). Similar to the embodiment shown in FIG. 1B, the electronic device shown in FIG. 6D also includes a conduction channel (e.g., having sol-gel metal oxides). The bottom gate is separated from the first electrode (e.g., source), the second electrode (e.g., drain) and the conduction channel (e.g., having sol-gel metal oxides) by at least one of a vacuum or an electrical insulator (gate insulator such as ALD Al₂O₃ or PECVD SiO₂). In this embodiment, a passivation layer is provided on top of the conduction channel.

FIG. 6E shows a schematic representation of an electronic device having a top gate (e.g., Mo or ITO) and bottom contact. The top gate is provided on top of passivation and top gate insulator. Similar to the embodiment shown in FIG. 1B, the electronic device shown in FIG. 6D also includes a conduction channel (e.g., having sol-gel metal oxides). In this embodiment, the conduction channel is provided on top of a substrate (e.g., glass or polyimide). The first and second electrodes (for example, source and drain respectively) are also provided on the substrate. The top gate is separated from the first electrode (e.g., source), the second electrode (e.g., drain) and the conduction channel (e.g., having sol-gel metal oxides) by at least one of a vacuum or an electrical insulator (passivation and top gate insulator such as PECVD SiO₂).

FIG. 6F shows a schematic representation of an electronic device having a dual gate (bottom and top gates, e.g., Mo or ITO) and bottom contact. The bottom gate (e.g., having Mo or ITO) is provided on a substrate such as a glass or a polyimide substrate. The top gate (e.g., having Mo or ITO) is provided on top of a passivation and top gate insulator (e.g., PECVD SiO₂). Similar to the embodiment shown in FIG. 1B, the electronic device shown in FIG. 6F also includes a conduction channel (e.g., having sol-gel metal oxides) that is provided between the top and bottom gates. The bottom gate is separated from the first electrode (e.g., source), the second electrode (e.g., drain) and the conduction channel (e.g., having sol-gel metal oxides) by at least one of a vacuum or an electrical insulator (bottom gate insulator). The top gate is separated from the first electrode (e.g., source), the second electrode (e.g., drain) and the conduction channel (e.g., having sol-gel metal oxides) by at least one of a vacuum or an electrical insulator (top gate insulator).

In the embodiments shown in FIGS. 6A-6F, similar to the embodiment shown in FIG. 1B, the conduction channel is in electrical connection with the first electrode and second electrode so as to be able to conduct a charge carrier current between the first electrode and the second electrode along a conduction path during an operating condition. The conduction channel includes a gradient semiconductor oxide composition transverse to the conduction path such that the gradient semiconductor oxide composition varies from indium rich to gallium rich, for example as shown in FIG. 1A. In an embodiment, the conduction channel includes sol-gel meta oxides. In an embodiment, the conduction channel 106 includes GZO/221/912 film. Although GZO/221/912 film is used as an example, any precursor combination that can produce ion concentration gradient and/or bandgap variation along the thickness direction can be used, such as Ga₂O₃/In₂O₃, Ga₂O₃/ZnO, Ga₂O₃/InZnOₓ, GaZnOₓ/In₂O₃, GaZnOₓ/InZnOₓ, ZnO/SnO₂, GaZnO/ZnO, GaZnO/SnO₂, etc.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

We claim:

1. An electronic device, comprising:
a first electrode;
a second electrode spaced apart from said first electrode; and
a conduction channel in electrical connection with said first and second electrodes so as to be able to conduct a charge carrier current between said first and second electrodes along a condition path during an operating condition,
wherein said conduction channel comprises a gradient semiconductor oxide composition transverse to said conduction path such that said gradient semiconductor oxide composition varies from indium rich to gallium rich.

2. The electronic device according to claim 1, further comprising a third electrode separated from said first electrode, said second electrode and said conduction channel by at least one of a vacuum or an electrical insulator.

3. The electronic device according to claim 2, wherein the third electrode comprises molybdenum or indium tin oxide (ITO).

4. The electronic device according to claim 2, wherein the electrical insulator comprises silicon oxide or aluminum oxide.

5. The electronic device according to claim 2, further comprising a fourth electrode separated from said first electrode, said second electrode and said conduction channel by at least one of a vacuum or an electrical insulator.

6. The electronic device according to claim 2, wherein the first electrode is a source electrode and the second electrode is a drain electrode or vice versa, and the third electrode is a gate electrode.

7. The electronic device according to claim 1, wherein the first electrode or the second electrode, or both comprise aluminum (Al), molybdenum (Mo), or both.

8. The electronic device according to claim 1, wherein the conduction channel comprises sol-gel meta oxides.

9. The electronic device according to claim 1, wherein the conduction channel comprises GZO/221/912 film.

10. The electronic device according to claim 1, wherein the conduction channel comprises a material selected from the group consisting Ga₂O₃/In₂O₃, Ga₂O₃/ZnO, Ga₂O₃/InZnOₓ, GaZnOₓ/In₂O₃, GaZnOₓ/InZnOₓ, ZnO/SnO₂, GaZnO/ZnO, and GaZnO/SnO₂.

11. The electronic device according to claim 1, further comprising a passivation layer disposed on the conduction channel.

12. A method of producing a conduction channel for an electronic device, comprising:
forming a first indium-rich metal-oxide gel film at least one of on or above a substrate;
forming a second indium rich metal-oxide gel film at least one of on or above said first indium-rich metal-oxide gel film, said second indium rich metal-oxide gel film being less indium rich than said first indium-rich metal-oxide gel film;
forming a gallium-rich metal-oxide gel film at least one of on or above said second indium-rich metal-oxide gel film; and
annealing said conduction channel to remove solvent molecules and volatile impurity elements and to form a cross-linked metal-oxygen framework.

13. The method according to claim 12, further comprising, before said annealing, forming a third indium rich metal-oxide gel film at least one of on or above said first indium-rich metal-oxide gel film and prior to forming said second indium rich metal-oxide gel film, said third indium rich metal-oxide gel film being less indium rich than said first indium-rich metal-oxide gel film and more indium rich than said second indium-rich metal-oxide gel film.

14. The method according to claim 12, further comprising, before said annealing, forming a second gallium-rich metal-oxide gel film at least one of on or above the first said gallium-rich metal-oxide gel film, said second gallium-rich metal-oxide gel film being more gallium rich than said first said gallium-rich metal-oxide gel film.

15. The method according to claim 12, wherein said forming said first indium-rich metal-oxide gel film comprises spin coating a first precursor solution followed by a first soft baking.

16. The method according to any one of claim 12, wherein said forming said second indium-rich metal-oxide gel film comprises spin coating a second precursor solution followed by a second soft baking.

17. The method according to any one of claim 12, wherein said forming said gallium-rich metal-oxide gel film comprises spin coating a third precursor solution followed by a third soft baking.

18. A method of producing an electronic device having a conduction channel comprising producing said conduction channel according to claim 12.

19. An electronic device produced according to the method of claim 12.
